(19) United States
(12) Patent Application Publication
(10) Pub. No.: US 2009/0208036 A1
(43) Pub. Date: Aug. 20, 2009

(54) MAGNETIC ALERT DETECTOR

(76) Inventor: Feng-Yu Liu, Taipei County (TW)

Correspondence Address: NORTH AMERICA INTELLECTUAL PROPERTY CORPORATION, P.O. BOX 506, MERRIFIELD, VA, 22116, US

(21) Appl. No.: 12/031,707

(22) Filed: Feb. 15, 2008

(51) Int. Cl. H03F 21/00; H04M 1/00

(52) U.S. Cl. 381/120; 455/567

(57) ABSTRACT

A tone alert amplifier includes a pickup coil, a filter unit, a converting unit, a micro-control unit, an amplifier, and a loud speaker unit. The pickup coil senses a magnetic signal to induce an input signal, and the filter unit performs a specific filtering operation upon the input signal to generate a filtered input signal. Next, the converting unit converts the filtered input signal into the digital signal, and the micro-control unit receives the digital signal to generate at least one output signal. Then the amplifier amplifies the output signal to generate an audio signal, and finally, the speaker unit outputs the audio signal.

### BACKGROUND OF THE INVENTION

1. Field of the Invention

The present invention relates to an audible alert amplifier, and more particularly, to a magnetic means of detection an alert condition generated by a cell phone, a pager, or other similar devices with loud speaker, transducer or vibrator.

2. Description of the Prior Art

A cell phone or pager user is unlikely to constantly have his cell phone or pager close at hand. Therefore, the user may not hear a ringtone generated from the cell phone or pager due to the sound volume degradation over distance, meaning that some important calls or messages will be missed. Although the sound volume of the cell phone or pager can be set to maximum, it is generally not loud enough for the user to notice when the user is at some distance from the cell phone/pager.

### SUMMARY OF THE INVENTION

It is therefore one of the objectives of the claimed invention to provide a tone alert amplifier by sensing a magnetic signal generated from a cell phone or a pager to output a high-volume alerttone to inform the user of the incoming call or message.

According to one embodiment of the present invention, the tone alert amplifier comprises of a pickup coil, a filter unit, a converting unit, a micro-control unit, an amplifier, and a loud speaker unit. The pickup coil senses a magnetic signal to induce an input signal, and the filter unit performs a specific filtering operation upon the input signal to generate a filtered input signal. Next, the converting unit converts the filtered input signal into the digital signal, and the micro-control unit receives the digital signal to generate at least one output signal. Then the amplifier amplifies the output signal to generate an audio signal, and finally, the loud speaker unit outputs the audio signal.

According to the tone alert amplifier provided by the present invention, when the cell phone or the pager rings or vibrates, the tone alert amplifier can sense the magnetic signal generated from the cell phone or the pager and output a louder alerttone to remind the user to pick up the cell phone or check message(s).

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a tone alert amplifier according to an exemplary embodiment of the present invention.

FIG. 2 is a block diagram illustrating a generalized architecture of an exemplary tone alert amplifier of the present invention.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

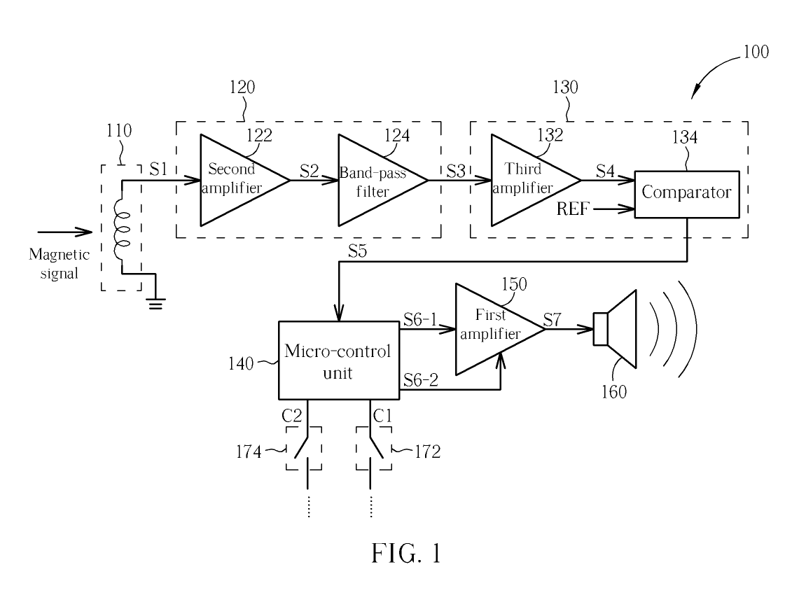

Please refer to FIG. 1. FIG. 1 is a diagram illustrating a tone alert amplifier 100 according to an exemplary embodiment of the present invention. As shown in FIG. 1, the tone alert amplifier 100 comprises a pickup coil 110, a first signal processing block 120, a second signal processing block 130, a micro-control unit 140, a first amplifier 150, a loud speaker unit 160, a first control key 172 and a second control key 174. In addition, the first signal processing block 120 comprises a second amplifier 122 and a band-pass filter 124, and the second signal processing block 130 comprises a third amplifier 132 and a comparator 134.

The tone alert amplifier 100 is positioned near a cell phone or a pager when the tone alert amplifier 100 is in use. When the cell phone or the pager is called into action (e.g., the cell phone or the pager rings or vibrates), magnetic components such as a transducer will generate a magnetic signal, where the magnetic signal here is a variation of magnetic flux generated from the magnetic component(s) of the cell phone or the pager. At this time, the pickup coil 110 senses the magnetic signal to induce an input signal S1. Because the magnetic signal generated by the cell phone or pager is very weak, the second amplifier 122 is utilized to amplify the input signal SI, and then an amplified input signal S2 is inputted into a band-pass filter 124 configured to filter out unwanted noises generated from other signal sources and to generate a filtered input signal S3 having signal components within the desired frequency band. Then the third amplifier 132 amplifies the filtered input signal S3, and the comparator 134 compares an amplified filtered input signal S4 with a reference level REF to generate a digital signal S5. For example, the comparator 134 acts as a data slicer for slicing the incoming amplified filtered input signal S4 (sine wave) by the reference level REF, thereby producing a digital signal (square wave) having 0's and 1's.

After this operation, the micro-control unit 140 receives the digital signal S5 to generate a first output signal S6-1 and a second output signal S6-2, where the first output signal S6-1 carries a tone data and the second output signal S6-2 carries an intensity data. The first amplifier 150 then amplifies the first output signal S6-1 to generate an audio signal S7 according to the second output signal S6-2. Finally, the loud speaker unit 160 outputs the audio signal S7 via acoustic waves so as to notify the user who might be at some distance from the cell phone or pager.

Specifically, as the tone alert amplifier 100 outputs the audio signal S7 due to action(s) of the cell phone or the pager, this outputted audio signal will be continuously played during a specific period even if the cell phone or the pager stops the action(s). Therefore, the exemplary tone alert amplifier 100 of the present invention can provide an option for allowing the user to program the specific period.

In addition, as shown in FIG. 1, the first control key 172 is coupled to the micro-control unit 140, and is utilized to provide a first control signal C1 to enable an alert amplifying function of the tone alert amplifier 100 when depressed. That is, if the first control key 172 is depressed, the tone alert amplifier 100 enters the alert amplifying function, and starts to perform the above-mentioned alert amplifying operations and outputs the audio signal when the cell phone or the pager is called into action. Furthermore, the second control key 174 is coupled to the micro-control unit 140, and is utilized to provide a second control signal C2 to disable the alert amplifying function when depressed. That is, if the tone alert amplifier 100 sounds an alarm due to actions of the cell phone or the pager, the user can depress the second control key 174 to disable the alert amplifying function.

It is noted that, in the tone alert amplifier 100, the band-pass filter 124 is utilized to filter out unwanted noises generated from other sources. However, in a specific operating environment where the tone alert amplifier 100 is in use, if there are no other magnetic sources near the magnetic alert amplifier 100, the band-pass filter 124 can be removed. In addition, the third amplifier 134 is utilized to amplify the filtered input signal and to ensure the digital signal generated from the comparator 134 is more accurate. The third amplifier 134 can also be removed, however, if the signal quality of the filtered input signal is good enough for the comparator 134. Moreover, using the comparator 134 to convert an analog signal (e.g., a sine wave) into a digital signal (e.g., a square wave) is for illustrative purposes only. In other words, any converting unit capable of converting an incoming signal into a digital signal can be employed to replace the comparator 134. In other words, the hardware configuration of either of the first and second signal processing blocks 120 and 130 is adjustable, depending upon design requirements. In addition, in the tone alert amplifier 100, the micro-control unit 140 generates the first output signal S6-1 carrying the tone data and the second output signal S6-2 carrying the intensity data respectively. The tone alert amplifier 100 can also generate only one output signal carrying an audio data only, and then the first amplifier 150 amplifies the output signal to generate the audio signal according to a preset intensity control. These alternative designs mentioned above are all in the scope of the present invention.

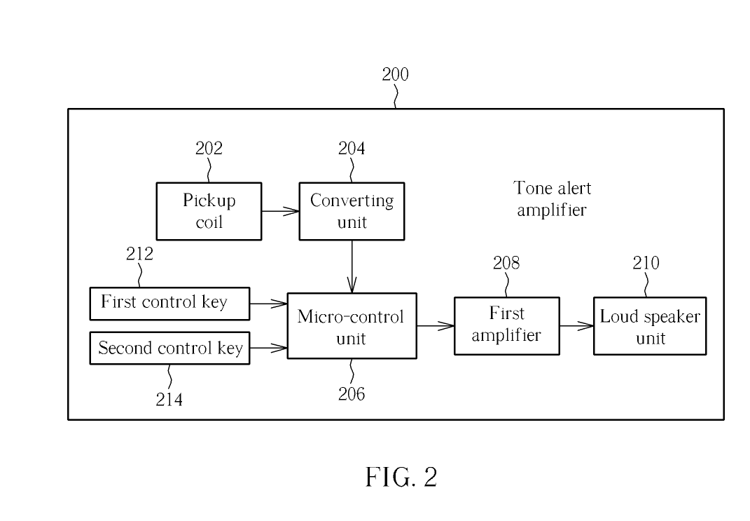

Please refer to FIG. 2, which is a block diagram illustrating a generalized architecture of an exemplary tone alert amplifier 200 of the present invention. The exemplary tone alert amplifier 200 includes a pickup coil 202 for sensing a magnetic signal to induce an input signal, a converting unit 204 for converting the input signal into a digital signal, a micro-control unit 206 for receiving the digital signal to generate at least one output signal, a first amplifier 208 for amplifying the output signal to generate an audio signal, a loud speaker unit 210 for outputting the audio signal, a first control key 212 for enabling an alert amplifying function of the magnetic alert amplifier when activated/depressed, and a second control key 214 for disabling the alert amplifying function when activated/depressed. After reading the above disclosure, an artisan skilled in the pertinent art can readily appreciate that, without departing from the spirit of the present invention, any modifications made to the base configuration shown in FIG. 2 are feasible. For example, the tone alert amplifier 100 shown in FIG. 1 is one implementation following the base configuration shown in FIG. 2.

In the present invention, the tone alert amplifier 100, 200 is an external device, and is positioned near to the cell phone or the pager when the tone alert amplifier 100, 200 is in use. In practice, however, the tone alert amplifier 100, 200 can also be integrated into apparatus such as a cell phone holder or other devices. These alternative designs are all in the scope of the present invention. In addition, the application of the tone alert amplifier 100, 200 is not limited to a cell phone or a pager.

Briefly summarized, the tone alert amplifier of the present invention comprises the pickup coil, the filter unit, the converting unit, the micro-control unit, the first amplifier, the loud speaker unit, the first control key and the second control key. The tone alert amplifier senses the magnetic signal generated from a cell phone or a pager to output a louder alerttone to remind the user to pick up the cell phone or check message(s). Therefore, the user will not miss important calls or messages.

Those skilled in the art will readily observe that numerous modifications and alterations of the device and method may be made while retaining the teachings of the invention.

What is claimed is:

1. A tone alert amplifier, comprising:
a pickup coil, for sensing a magnetic signal to induce an input signal;
a converting unit, coupled to the pickup coil, for converting the input signal into a digital signal;
a micro-control unit, coupled to the converting unit, for receiving the digital signal to generate at least one output signal;
a first amplifier, coupled to the micro-control unit, for amplifying the output signal to generate an audio signal; and
a loud speaker unit, coupled to the first amplifier, for outputting the audio signal.

2. The tone alert amplifier of claim 1, further comprising:
a filter unit, coupled between the pickup coil and the converting unit, for performing a specific filtering operation upon the input signal to generate a filtered input signal, wherein the converting unit converts the filtered input signal into the digital signal.

3. The tone alert amplifier of claim 2, wherein the filter unit comprises a band-pass filter for band-pass filtering the input signal.

4. The tone alert amplifier of claim 2, wherein the converting unit comprises a comparator for comparing the filtered input signal with a reference level to generate the digital signal.

5. The tone alert amplifier of claim 2, further comprising:
a second amplifier, coupled between the pickup coil and the filter unit, for amplifying the input signal.

6. The tone alert amplifier of claim 5, further comprising:
a third amplifier, coupled between the filter unit and the converting unit, for amplifying the filtered input signal.

7. The tone alert amplifier of claim 1, wherein the converting unit comprises a comparator for comparing the input signal with a reference level to generate the digital signal.

8. The tone alert amplifier of claim 1, further comprising:
a second amplifier, coupled between the pickup coil and the converting unit, for amplifying the input signal.

9. The tone alert amplifier of claim 1, wherein the magnetic signal is generated from a cell phone or a pager, or other similar devices with loud speaker, transducer or vibrator.

10. The tone alert amplifier of claim 1, further comprising:
a first control key, coupled to the micro-control unit, for providing a first control signal to enable an alert amplifying function of the tone alert amplifier; and
a second control key, coupled to the micro-control unit, for providing a second control signal to disable the alert amplifying function.

11. The tone alert amplifier of claim 1, wherein the micro-control unit receives the digital signal to generate a plurality of output signals including a first output signal carrying a tone data and a second output signal carrying an intensity data; and the first amplifier amplifies the first output signal to generate the audio signal according to the second output signal.
